(19) United States
(12) Patent Application Publication
(10) Pub. No.: US 2013/0221816 A1
(43) Pub. Date: Aug. 29, 2013

(54) CASING OF ELECTRONIC DEVICE AND METHOD OF MANUFACTURING THE SAME

(71) Applicant: HTC CORPORATION, (US)

(72) Inventors: Jethro Liou, San Francisco, CA (US); Feng-Chen Chang, Taoyuan County (TW); Chih-Ling Chien, Taoyuan County (TW)

(73) Assignee: HTC CORPORATION, Taoyuan County (TW)

(21) Appl. No.: 13/684,076

(22) Filed: Nov. 21, 2012

Related U.S. Application Data
(60) Provisional application No. 61/602,626, filed on Feb. 24, 2012.

(51) Int. Cl. H05K 5/02; H05K 13/00

(52) U.S. Cl. CPC H05K 5/02; H05K 13/0046
USPC 312/223.1; 205/333; 205/222; 205/199; 205/170; 205/116

(57) ABSTRACT

A manufacturing method of a casing of electronic device including the following steps is provided. A casing body is provided, and the material of the casing body being metal. An oxide ceramic layer is formed on a surface of the casing body, wherein the step of forming the oxide ceramic layer on the surface of the casing body is a Micro Arc Oxidation (MAO) process. A casing of electronic device including a casing body and an oxide ceramic layer is also disclosed. The material of the casing body is metal. The oxide ceramic layer is located on a surface of the casing body.

### CROSS-REFERENCE TO RELATED APPLICATION

This application claims the priority benefits of U.S. provisional application Ser. No. 61/602,626, filed on Feb. 24, 2012. The entirety of the above-mentioned patent applications is hereby incorporated by reference herein and made a part of this specification.

### BACKGROUND OF THE INVENTION

1. Field of the Invention

The application relates to a casing and a manufacturing method of a casing, and more particularly, to a casing of electronic device and a manufacturing method of a casing of electronic device.

2. Description of Related Art

In recent years, as the technology industry becomes increasingly developed, electronic products provide users with the desired information that is easily accessible in everyday life. On the other hand, electronic devices are developing toward a convenient, multi-functional, and aesthetic design direction to provide users with more options. At the same time, electronic products are gradually developing toward a slim and light trend, therefore gradually increasing the demand of electronic devices.

Electronic devices are, for instance, mobile phones, Personal Digital Assistants (PDAs), and smart phones, and these electronic devices usually have the advantages of small size and lightweight. Users may carry the electronic devices around, and may operate the electronic devices by holding them. Therefore, electronic devices are very convenient.

However, the casing of electronic device becomes damaged easily during use from bumping, or the surface of the casing of electronic device becomes scratched from contact with sharp metal objects such as keys. Moreover, when users hold electronic devices frequently, fingerprints and dirt from the hands of the users easily remain on the surfaces of the electronic devices.

### SUMMARY OF THE INVENTION

The application provides a manufacturing method of a casing of electronic device that enhances the mechanical strength of the casing of electronic device.

The application provides a casing of electronic device having higher mechanical strength.

The application provides a manufacturing method of a casing of electronic device including the following steps. A casing body is provided, and the material of the casing body being metal. An oxide ceramic layer is formed on a surface of the casing body, wherein the step of forming the oxide ceramic layer on the surface of the casing body is a Micro Arc Oxidation (MAO) process.

The application further provides a casing of electronic device including a casing body and an oxide ceramic layer. The material of the casing body is metal. The oxide ceramic layer is located on a surface of the casing body.

In summary, the application provides a manufacturing method of a casing of electronic device, wherein an oxide ceramic layer is formed on the metal casing body by the Micro Arc Oxidation process to enhance the mechanical strength of the casing of electronic device. Moreover, the application further provides a casing of electronic device having an oxide ceramic layer located on the surface of the casing body. Accordingly, the casing of electronic device has higher mechanical strength.

In order to make the aforementioned features and advantages of the application more comprehensible, embodiments accompanied with figures are described in detail below.

### BRIEF DESCRIPTION OF THE DRAWINGS

The accompanying drawings are included to provide a further understanding of the application, and are incorporated in and constitute a part of this specification. The drawings illustrate embodiments of the application and, together with the description, serve to explain the principles of the application.

FIG. 1 is a flow chart of the manufacturing method of the casing of electronic device according to an embodiment of the application.

FIG. 2A to FIG. 2D are cross-sectional schematic diagrams of the manufacturing method of the casing of electronic device of FIG. 1.

FIG. 3 is a cross-sectional schematic diagram of the casing of electronic device according to another embodiment of the application.

### DESCRIPTION OF THE EMBODIMENTS

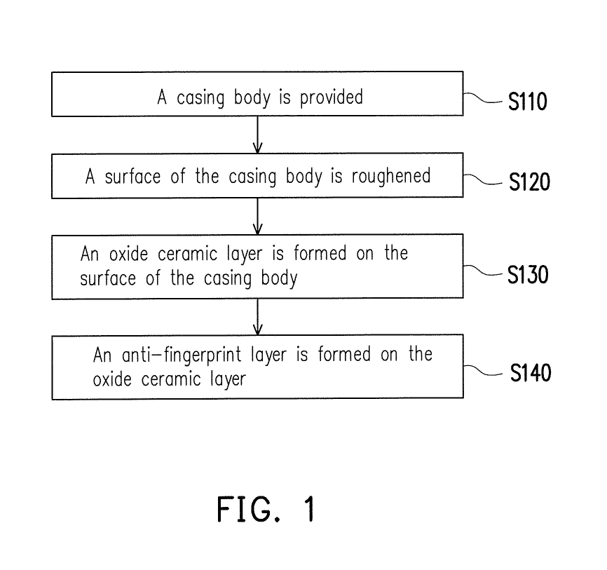

FIG. 1 is a flow chart of the manufacturing method of the casing of electronic device according to an embodiment of the application. Referring to FIG. 1, in the embodiment, the manufacturing process of the casing of electronic device 100 is as follows: in the step S110, a casing body 110 is provided. In the step S120, a surface S 1 of the casing body 110 is roughened. In the step S130, an oxide ceramic layer 120 is formed on the surface S1 of the casing body 110. In the step S140, an anti-fingerprint layer 130 is formed on the oxide ceramic layer 120.

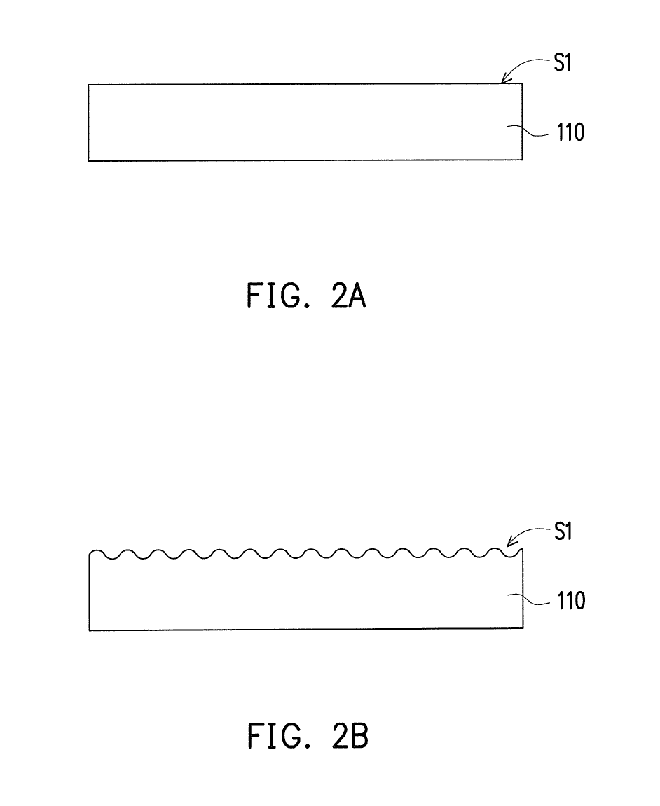

FIG. 2A to FIG. 2D are cross-sectional schematic diagrams of the manufacturing method of the casing of electronic device of FIG. 1. In the embodiment, the casing of electronic device 100 is, for instance, the casing of mobile phones or smart phones, but the application does not limit the scope of the electronic device. FIG. 2A to FIG. 2D sequentially illustrate the manufacturing process of the casing of electronic device 100. The manufacturing process of the casing of electronic device 100 of the embodiment is sequentially explained in the following with FIG. 1 and FIG. 2A to FIG. 2D.

Referring to FIG. 1 and FIG. 2A, first, in the step S110, the casing body 110 is provided. In the embodiment, the material of the casing body 110 is metal, such as aluminum alloys. However, in other embodiments, the material of the casing body may be magnesium alloys, titanium alloys, or other metals, but the application is not limited thereto. Pretreatment process may be applied to the casing body 110, such as cleaning the surface S1 of the casing body 110 to remove grease or impurities.

Referring to FIG. 1 and FIG. 2B, then, in the step S120, the surface S1 of the casing body 110 is roughened. In the embodiment, the casing body 110 is roughened by a sandblasting process for the surface S1 with pretreatment. The material of the sandblast is, for instance, ceramic sand or glass sand, but the application is not limited thereto. Moreover, in other embodiments, the surface S1 of the casing body 110 may be roughened by vapor deposition, or the surface S1 may also not be roughened. The application does not limit the roughening method of the surface S1, and also does not require roughening of the surface S1.

Referring to FIG. 1 and FIG. 2C, then, in the step S130, the oxide ceramic layer 120 is formed on the surface S1 of the casing body 110. In the embodiment, the surface S1 of the casing body 110 is already roughened, and the oxide ceramic layer 120 is formed on the roughened surface S1 of the casing body 110. Therefore, the oxide ceramic layer 120 may have the more smooth surface S2.

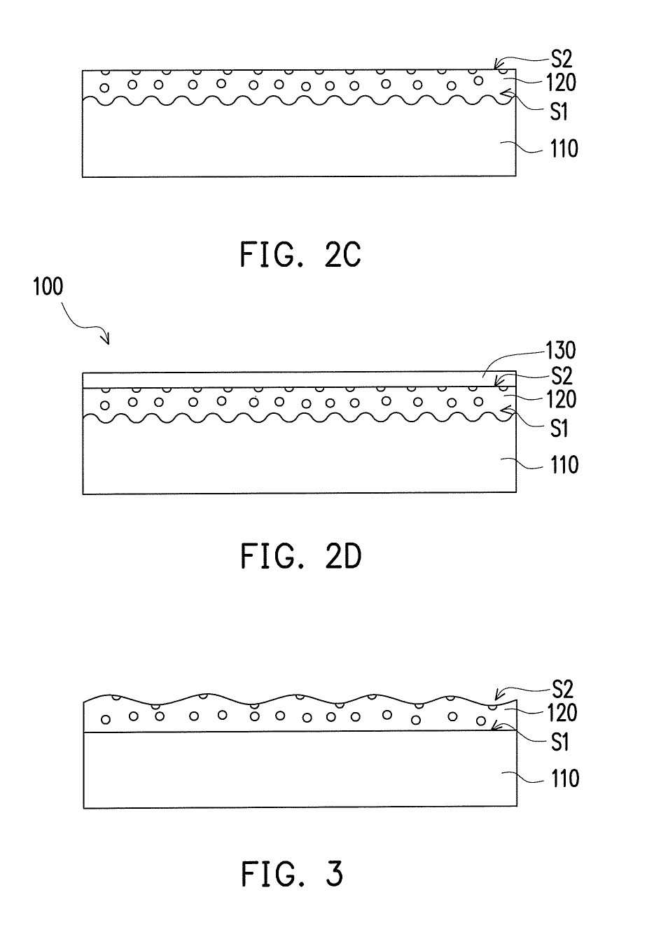

However, in other embodiments, the oxide ceramic layer 120 may be formed on the surface S1 of the casing body 110 that has not been roughened. FIG. 3 is a cross-sectional schematic diagram of the casing of electronic device according to another embodiment of the application. Referring to FIG. 3, in the embodiment, the oxide ceramic layer 120 is formed on the surface S1 of the casing body 110 that has not been roughened, so that the oxide ceramic layer 120 produces the uneven surface S2 during the formation. It may be known from FIG. 2C and FIG. 3C that, before forming the oxide ceramic layer 120 on the surface S1 of the casing body 110, the surface S1 is first roughened so that the oxide ceramic layer 120 has a surface S2 more smooth, but the application is not limited thereto.

Referring to FIG. 1 and FIG. 2C, in the embodiment, the step of forming the oxide ceramic layer 120 on the surface S1 of the casing body 110 is a Micro Arc Oxidation (MAO) process. The Micro Arc Oxidation process may form an oxide ceramic layer having a base metal on the surface of the metal object to enhance the mechanical strength of the metal object.

Simply put, after immersing the metal casing body 110 into an electrolyte solution and applying electric current, an oxide thin film layer is produced on the surface S1 of the casing body 110. When the voltage applied to the casing body 110 exceeds the specified critical value, the partial regions of the oxide ceramic layer relatively weak are punctured by the electric current and produce a micro arc discharge phenomenon, resulting in the surface S1 of the casing body 110 producing arc spots or sparks. Then, the partial regions of the oxide ceramic layer punctured by the electric current regenerate a new oxide thin film layer, and another partial regions of the oxide thin film layer relatively weak are punctured by the electric current and produces the micro arc discharge phenomenon. The steps are repeated and the oxide thin film layer forms a uniform oxide ceramic layer 120 on the surface S1 of the casing body 110.

In the embodiment, the values of the process conditions of the Micro Arc Oxidation process are as follows: the solution temperature is between 35° C. and 50° C., the voltage is between 400 V and 600 V, the thickness is between 15 μm and 25 μm, and the time is between 15 minutes and 25 minutes. The values are selected for the process conditions of the Micro Arc Oxidation process of the embodiment. In other embodiments, the values of the process conditions may be adjusted according to the demand of the Micro Arc Oxidation process, but the application is not limited thereto.

On the other hand, after the oxide ceramic layer 120 is formed on the surface S1 of the casing body 110 by the Micro Arc Oxidation process, the oxide ceramic layer 120 has a colored appearance. The color of the colored appearance of the oxide ceramic layer 120 depends on the material of the electrolyte solution used for the oxide ceramic layer 120 in the Micro Arc Oxidation process. In the embodiment, the colored appearance of the oxide ceramic layer 120 is black, and in other embodiments, depending on the demand of the colored appearance of the casing body 110, the colored appearance of the oxide ceramic layer may be grey, white, or other colors, but the application is not limited thereto.

After forming the oxide ceramic layer 120 on the surface S1 of the casing body 110, the casing of electronic device 100 is largely formed. Therefore, the surface S2 of the oxide ceramic layer 120 may be regarded as the contact surface when the user touches the casing of electronic device 100. The oxide ceramic layer 120 formed by the Micro Arc Oxidation process has irregular voids as shown in FIG. 2C, therefore the surface S2 of the oxide ceramic layer 120 is a matte surface and feels rough. Therefore, in the embodiment, after forming the oxide ceramic layer 120 on the surface S1 of the casing body 110, the casing of electronic device 100 may fill the voids on the surface S2 of the oxide ceramic layer 120 or polish the oxide ceramic layer 120, so that the surface S2 of the oxide ceramic layer 120 is more smooth.

In particular, in the embodiment, after forming the oxide ceramic layer 120 on the surface S1, the casing of electronic device 100 may fill the irregular voids on the surface S2 of the oxide ceramic layer 120 by a sealing process, wherein the filling method includes electroplating a protective material, but the application is not limited thereto. In other embodiments, the casing of electronic device 100 may not fill the voids on the surface S2 to keep the rough feel of the surface S2, but the application is not limited thereto.

Moreover, in the embodiment, after forming the oxide ceramic layer 120 on the surface S1, the surface S2 of the oxide ceramic layer 120 of the casing of electronic device 100 may transform from a matte surface to a glossy surface by polishing, and the glossy surface is more smooth than the matte surface. Therefore, the casing of electronic device 100 may make the surface S2 more smooth by polishing the oxide ceramic layer 120, and the visual effect of the casing of electronic device 100 changes from that of a matte surface to that of a glossy surface. Furthermore, the glossy surface formed on the oxide ceramic layer 120 by polishing is essentially a minor surface. Therefore, the minor surface of the oxide ceramic layer 120 may provide the casing of electronic device 100 a different visual effect by reflecting images recognizable by the naked eye. However, in other embodiments, the casing of electronic device 100 may not polish the oxide ceramic layer 120 to keep the matte effect, but the application is not limited thereto.

Referring to FIG. 1 and FIG. 2D, then, in the step S140, the anti-fingerprint layer 130 is formed on the oxide ceramic layer 120, wherein the anti-fingerprint layer 130 may be transparent or light transmissive. In the embodiment, since the user operates the electronic device by holding the casing of electronic device 100, so that fingerprints and dirt from the hands of the user is easily remained in the voids on the surface S2 of the oxide ceramic layer 120. Therefore, the casing of electronic device 100 of the embodiment further includes the anti-fingerprint layer 130 located on the oxide ceramic layer 120, and the contact surface of the casing of electronic device 100 the user touches changes from the surface S2 of the oxide ceramic layer 120 to the anti-fingerprint layer 130, as shown in FIG. 2D. Accordingly, the surface S2 of the oxide ceramic layer 120 is more smooth, and may prevent fingerprints or dirt from remaining on the casing of electronic device 100.

In the embodiment, the step of forming the anti-fingerprint layer 130 on the oxide ceramic layer 120 includes coating the anti-fingerprint coating, such as forming the anti-fingerprint coating on the surface S2 of the oxide ceramic layer 120 by spray coating. Table 1 below explains the ingredients of the anti-fingerprint coating of the embodiment, but the application is not limited thereto, as coatings with other ingredients may also be used in other embodiments.

TABLE 1
Ingredients of the Anti-Fingerprint Coating of the Embodiment

| Ingredient | CAS Number | Content % |
|---|---|---|
| Xylene | 1330-20-7 | 15-25 |
| 2-butoxyethanol | 111-76-2 | 5-15 |
| Methyl ethyl ketone | 78-93-3 | 5-15 |
| Toluene | 108-88-3 | 5-15 |
| 2-methylpropanol | 78-83-1 | 5-15 |
| Ethylbenzene | 100-41-4 | 1-5 |
| Epoxy resin | 25036-25-3 | 1-5 |
| Methyl isobutyl ketone | 108-10-1 | 1-5 |

The surface of the anti-fingerprint layer 130 is more smooth than the surface of the oxide ceramic layer 120, and the anti-fingerprint layer 130 does not affect the texture of the surface S2 of the oxide ceramic layer 120. Therefore, the anti-fingerprint layer 130 may be formed on a polished surface S2 of the oxide ceramic layer 120 so that the casing of electronic device 100 has the visual effect of a glossy surface or even of a mirror surface. The anti-fingerprint layer 130 may also be formed on an unpolished surface S2 of the oxide ceramic layer 120 so that the casing of electronic device 100 has the visual effect of a matte surface.

Since the anti-fingerprint layer 130 is located on the outermost layer of the casing of electronic device 100, so that whether or not the oxide ceramic layer 120 is polished does not affect the tactile effect of the casing of electronic device 100. Therefore, the anti-fingerprint layer 130 may let the casing of electronic device 100 have a more smooth surface, and may prevent fingerprints or dirt from remaining on the casing of electronic device 100.

After forming the anti-fingerprint layer 130 on the oxide ceramic layer 120, the casing of electronic device 100 is complete. Referring to FIG. 2D, in the embodiment, the casing of electronic device 100 includes the casing body 110, the oxide ceramic layer 120, and the anti-fingerprint layer 130. The oxide ceramic layer 120 is located on the surface S1 of the casing body 110 and has a colored appearance, wherein the surface S1 of the casing body 110 is a roughened surface. The anti-fingerprint layer 130 is located on the oxide ceramic layer 120, and the surface of the anti-fingerprint layer 130 is more smooth than the surface of the oxide ceramic layer 120.

The casing of electronic device 100 may be regarded as a bilayer structure composed of the metal casing body 110 and the oxide ceramic layer 120, and the casing of electronic device 100 may also have the anti-fingerprint layer 130 formed on the oxide ceramic layer 120. Compared to the traditional casing of electronic device having the problem of bumping often and becoming cracked or deformed, the casing of electronic device 100 has the oxide ceramic layer 120 to enhance the mechanical strength of the casing of electronic device 100, and has the anti-fingerprint layer 130 to prevent fingerprints or dirt from remaining on the casing of electronic device 100. Accordingly, the appearance, the aesthetics, and the durability of the casing of electronic device 100 are significantly enhanced.

In summary, the application provides a manufacturing method of a casing of electronic device, wherein the oxide ceramic layer having a colored appearance is formed on the metal casing body by the Micro Arc Oxidation process to enhance the mechanical strength and the texture of the casing of electronic device. Moreover, the application further provides a casing of electronic device having an oxide ceramic layer located on the surface of the casing body. Moreover, the casing of electronic device also has the anti-fingerprint layer located on the oxide ceramic layer. The surface of the anti-fingerprint layer is more smooth than the surface of the oxide ceramic layer to prevent fingerprints or dirt from remaining in the voids on the oxide ceramic layer, and has a more smooth tactility. Accordingly, the casing of electronic device has higher mechanical strength and better texture.

Although the application has been described with reference to the above embodiments, it will be apparent to one of the ordinary skill in the art that modifications and variations to the described embodiments may be made without departing from the spirit and scope of the application. Accordingly, the scope of the application will be defined by the attached claims not by the above detailed descriptions.

What is claimed is:

1. A manufacturing method of a casing of electronic device, comprising:
providing a casing body, wherein the material of the casing body is metal; and
forming an oxide ceramic layer on a surface of the casing body, wherein the step of forming the oxide ceramic layer on the surface of the casing body is a Micro Arc Oxidation (MAO) process.

2. The method of claim 1, further comprising:
after the step of providing the casing body, roughening a surface of the casing body, and the oxide ceramic layer is formed on the roughened surface of the casing body.

3. The method of claim 1, further comprising:
forming an anti-fingerprint layer (AFP layer) on the oxide ceramic layer after the step of forming the oxide ceramic layer, wherein the surface of the anti-fingerprint layer is more smooth than the surface of the oxide ceramic layer.

4. The method of claim 3, wherein the step of forming the anti-fingerprint layer on the oxide ceramic layer comprises coating an anti-fingerprint coating.

5. The method of claim 1, further comprising:
filling the voids on the surface of the oxide ceramic layer after the step of forming the oxide ceramic layer.

6. The method of claim 1, further comprising:
polishing the oxide ceramic layer after the step of forming the oxide ceramic layer, so as to transform the surface of the oxide ceramic layer from a matte surface to a glossy surface, wherein the glossy surface is more smooth than the matte surface.

7. The method of claim 6, wherein the glossy surface is a mirror surface.

8. The method of claim 1, wherein the oxide ceramic layer has a colored appearance.

9. The method of claim 8, wherein the colored appearance comprises black, grey, and white.

10. A casing of electronic device, comprising:
a casing body, wherein the material of the casing body is metal; and
an oxide ceramic layer, located on a surface of the casing body.

11. The casing of electronic device of claim 10, wherein the surface of the casing body is a roughened surface.

12. The casing of electronic device of claim 10, further comprising:
an anti-fingerprint layer, located on the oxide ceramic layer, wherein the surface of the anti-fingerprint layer is more smooth than the surface of the oxide ceramic layer.

13. The casing of electronic device of claim 10, wherein the surface of the oxide ceramic layer transforms from a matte surface to a glossy surface after polishing, and the glossy surface is more smooth than the matte surface.

14. The casing of electronic device of claim 13, wherein the glossy surface is a mirror surface.

15. The casing of electronic device of claim 10, wherein the oxide ceramic layer has a colored appearance.

16. The casing of electronic device of claim 15, wherein the colored appearance comprises black, grey, and white.
